(19) United States
(12) Patent Application Publication
(10) Pub. No.: US 2007/0221704 A1
(43) Pub. Date: Sep. 27, 2007

(54) METHOD OF MANUFACTURING CIRCUIT DEVICE

(75) Inventors: Sadamichi Takakusaki, Gunma (JP); Noriaki Sakamoto, Gunma (JP); Motoichi Nezu, Gunma (JP); Yusuke Igarashi, Gunma (JP)

Correspondence Address: WATCHSTONE P + D, 1250 CONNECTICUT AVENUE, N.W., SUITE 700, WASHINGTON, DC, 20036, US

(73) Assignee: SANYO ELECTRIC CO., LTD., Osaka (JP)

(21) Appl. No.: 11/307,278

(22) Filed: Jan. 30, 2006

(30) Foreign Application Priority Data
Jan. 31, 2005 (JP) 2005-023329
Dec. 28, 2005 (JP) 2005-380132

(51) Int. Cl. A47J 36/02

(52) U.S. Cl. 228/101

(57) ABSTRACT

A method of manufacturing a circuit device of the present invention comprises the steps of: forming a conductive pattern including a first pad and a second pad on the surface of a substrate; applying a solder paste to the surface of the first pad and then thermally melting the solder paste, thus forming solder; fixing a circuit element to the second pad; and fixing a circuit element to the first pad with the solder therebetween. Furthermore, a flux constituting the solder paste contains sulfur. Since the sulfur is mixed into the solder paste, surface tension of the solder paste is lowered; accordingly occurrence of sink is suppressed.

### CROSS-REFERENCE TO RELATED APPLICATIONS

Priority is claimed to Japanese Patent Application Numbers JP2005-023329, filed on Jan. 31, 2005, and JP2005-380132, filed on Dec. 28, 2005, the disclosures of which are incorporated herein by reference in its entireties.

### BACKGROUND OF THE INVENTION

1. Field of the Invention

The present invention relates to a method of manufacturing a circuit device, and more particularly relates to a method of manufacturing a circuit device in which large circuit elements are connected by use of solder.

2. Description of the Related Art

With reference to FIGS. 9A to 10B, a method of manufacturing a conventional circuit device will be explained. Here, description will be given of a method of manufacturing a hybrid integrated circuit device in which a conductive pattern 108 and circuit elements are formed on a surface of a substrate 106. This technology is described for instance in Japanese Patent Application Publication No. 2002-134682.

As shown in FIG. 9A, first, a solder 109A is formed on a surface of the conductive pattern 108 formed on the surface of the substrate 106. The substrate 106 is, for example, a metal substrate made of metal such as aluminum. The conductive pattern 108 and the substrate 106 are insulated from each other by an insulating layer 107. The conductive pattern 108 forms pads 108A, 108B and 108C. A heat sink is fixed to an upper part of the pad 108A in a subsequent step. A small signal transistor is fixed to the pad 108B in a subsequent step. A lead is fixed to the pad 108C in a subsequent step. Here, the solder 109A is formed on each of surfaces of the pad 108A, which is a relatively large pad, and the pad 108C.

As shown in FIG. 9B, next, a small signal transistor 104C and a chip component 104B are fixed by use of a solder 109B. In this step, heating is performed until the solder 109B, which connects the transistor 104C and the like, is melted. Therefore, the solder 109A formed on each of the pads 108A and 108C in the preceding step is also melted.

As shown in FIG. 9C, next, the small signal transistor 104C and a predetermined conductive pattern 108 are connected to each other by use of a thin wire 105B.

As shown in FIG. 10A, next, the solder 109A previously formed on each of the pads 108A and 108C is melted to fix a heat sink 111 and a lead 101. Here, the heat sink 111 having a power transistor 104A mounted thereon is fixed onto the pad 108A with the previously formed solder 109A interposed therebetween. Furthermore, a desired conductive pattern 108 and the transistor 104A are connected to each other by use of a thick wire 105A.

As shown in FIG. 10B, a sealing resin 102 is formed so as to cover the circuit elements and the conductive pattern 108 which are formed on the surface of the substrate 106. By the above steps, a hybrid integrated circuit device 100 is manufactured.

However, as shown in FIGS. 11A to 11C, in the step of forming a solder 109 on the surfaces of a pad 108A, there is a problem of sink in the solder 109. FIG. 11A is a plan view showing a substrate 106 above which sink has occurred, FIG. 11B is a cross-sectional view of FIG. 11A, and FIG. 11C is a magnified cross-sectional view showing a part where sink has occurred.

As shown in FIGS. 11A and 11B, “sink” is a phenomenon that the solder 109 is accumulated on one side or the other when a solder paste applied to the entire surface of the pad 108A is melted. Particularly, the pad 108A to which a heat sink 111 is fixed is formed to be shaped like a large rectangle having sides each of which, for example, is 9 mm or larger. Therefore, compared with other parts, a large amount of solder is deposited on the upper part of the pad 108A. Accordingly, high surface tension acts on the melted solder 109. Thus, the sink of solder occurs.

When the sink of solder 109 occurs, the pad 108A and a circuit element are not connected to each other in the part where the sink occurs. Accordingly, heat resistance in the part where the sink of solder has occurred is increased. Furthermore, since strength of the connection is lowered by the occurrence of sink, reliability of the solder connection part relative to temperature variations is lowered.

As shown in FIG. 11C, generation of an alloy layer 110 between the pad 108A and the solder 109A is one of the causes of the occurrence of the sink. When the solder paste is attached to the upper part of the pad 108A and heated and melted, an intermetallic compound is formed, which is made of copper that is a material of the pad 108A and tin that is a material of the solder. In FIG. 11C, a layer made of the intermetallic compound is indicated by the alloy layer 110. To be more specific, a thickness of the alloy layer 110 is about several μm, and an intermetallic compound having a composition of Cu₆Sn₅ or Cu₃Sn is formed. This alloy layer 110 has poor solder wettability compared with copper that is the material of the pad 108A. Accordingly, formation of the alloy layer 110 having the poor solder wettability causes the sink of the solder. In the below description, the alloy layer made of copper and tin is called a Cu/Sn alloy layer.

Furthermore, activation of an interface between the alloy layer 110 and the solder 109A by melting of the alloy made of copper and tin into the solder 109A is also one of the causes of the occurrence of the sink described above.

FIG. 12A is a cross-sectional view of the substrate 106 in which the above-described sink occurs. FIG. 12B is a SEM (scanning electron microscopy) image of a cross section of the boundary between the pad 108A and the solder 109A.

As shown in FIG. 12B, on the boundary between the pad 108A and the solder 109A, the alloy layer 110 made of copper and tin is generated. As described above, since the solder 109A is melted more than once, formation of the alloy layer 110 which is as thick as about 5 μm or more, for example, induces sink. Moreover, the intermetallic compound made of copper and tin is formed at a high rate. Thus, activation of the boundary between the solder 109A and the pad 108A is also the cause of occurrence of the sink. Furthermore, the intermetallic compound is formed not only in the boundary therebetween but also in the solder 109A, for example.

Furthermore, although not clearly shown in the SEM image, a number of hemispherical protrusions, each of which has a size of about 5 to 10 μm, for example, and is made of the intermetallic compound, are formed on the entire upper surface of the alloy layer 110. The alloy layer 110 has a relatively smooth surface. The formation of the protrusions reduces an interface resistance on the upper surface of the alloy layer 110 and leads to a situation where the solder 109A is likely to slip on the surface. Thus, occurrence of the sink described above is promoted.

Meanwhile, in consideration of the environments, lead-free solder has recently been used. If the lead-free solder is used as the solder 109A, the problem of the sink described above occurs more prominently. This is because the lead-free solder contains more tin than lead eutectic solder does. To be more specific, a proportion of tin contained in a general lead eutectic solder is about 60 wt %. On the other hand, a proportion of tin contained in the lead-free solder is about 90 wt %, which is relatively large. Furthermore, when the lead-free solder is melted, a temperature is higher than that on the occasion when the lead eutectic solder is melted. This is also the cause of formation of the thick alloy layer 110. To be more specific, when the lead eutectic solder is melted, the temperature is about 200° C. Meanwhile, when a lead-free solder having a composition of Sn-3.0Ag-0.5Cu, for example, is melted, the temperature is about 240° C. As described above, the higher the melting temperature is, the more the chemical reaction is accelerated. Thus, the alloy layer 110 having poor wettability is formed to be thicker.

### SUMMARY OF THE INVENTION

The present invention was made in view of the forgoing problems. The present invention provides a method of manufacturing a circuit device in which reliability of a solder connection part is improved by suppressing the occurrence of the sink of solder.

The present invention provides a method of manufacturing a circuit device that includes: forming a conductive pattern including a pad on a surface of a substrate; applying a solder paste to a surface of the pad; and placing a circuit element on the solder paste and then thermally melting the solder paste, thus fixing the circuit element to the pad, wherein the solder paste contains sulfur.

The present invention also provides a method of manufacturing a circuit device that includes: forming a conductive pattern including a first pad and a second pad smaller than the first pad on a surface of a substrate; applying a solder paste to a surface of the first pad and then thermally melting the solder paste, thus forming solder on the surface of the first pad; fixing a circuit element to the second pad; and fixing the circuit element to the first pad while interposing the solder therebetween; wherein the solder paste applied to the first pad contains sulfur.

### BRIEF DESCRIPTION OF THE DRAWINGS

FIG. 1A is a perspective view showing a circuit device of a first embodiment of the present invention, and FIGS. 1B and 1C are cross-sectional views showing the circuit device.

FIG. 2A is a plan view showing a method of manufacturing a circuit device of a second embodiment of the present invention and FIG. 2B is a cross-sectional view showing the method.

FIGS. 3A, 3B and 3D are cross-sectional views showing the method of manufacturing a circuit device of the second embodiment of the present invention and FIG. 3C is a plan view showing the method.

FIGS. 4A and 4B are cross-sectional views showing the method of manufacturing a circuit device of the second embodiment of the present invention and FIG. 4C is a plan view showing the method.

FIG. 5A is a cross-sectional view showing the method of manufacturing a circuit device of the second embodiment of the present invention and FIG. 5B is an SEM image.

FIGS. 6A and 6B are cross-sectional views showing the method of manufacturing a circuit device of the second embodiment of the present invention.

FIGS. 7A and 7B are cross-sectional views showing the method of manufacturing a circuit device of the second embodiment of the present invention.

FIGS. 8A to 8D are cross-sectional views showing the method of manufacturing a circuit device of a third embodiment of the present invention.

FIGS. 9A to 9C are cross-sectional views showing a conventional method of manufacturing a circuit device.

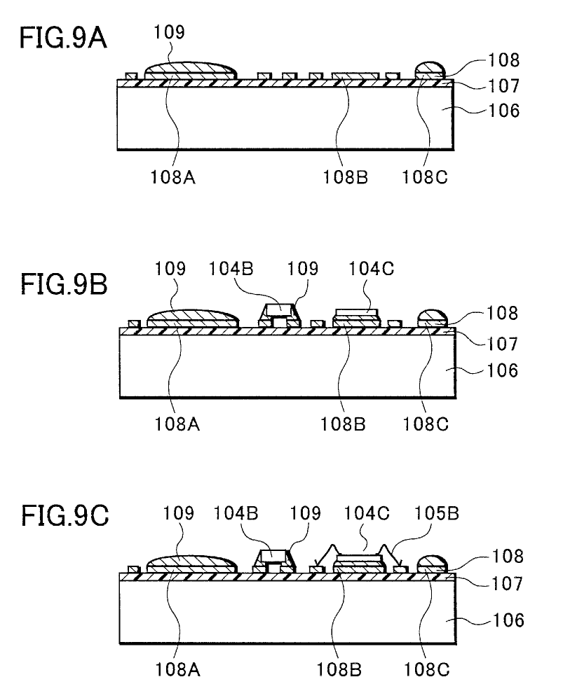

FIGS. 10A and 10B are cross-sectional views showing the conventional method of manufacturing a circuit device.

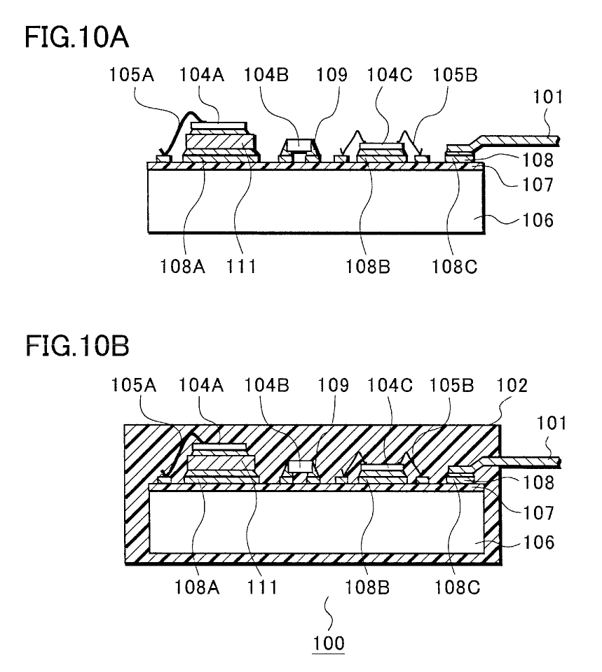

FIG. 11A is a plan view showing the conventional method of manufacturing a circuit device, FIG. 11B is a cross-sectional view showing the method, and FIG. 11C is a magnified cross-sectional view.

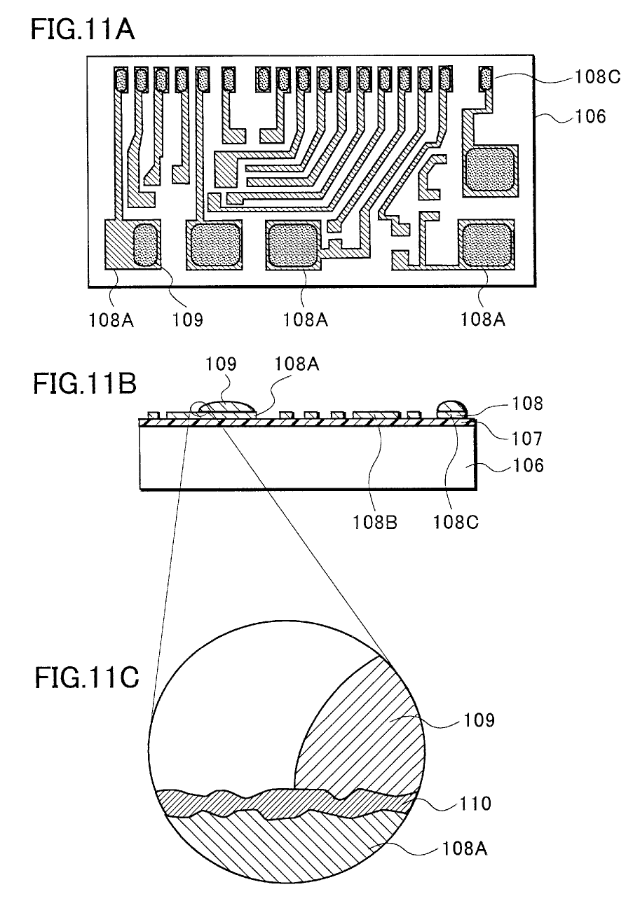

FIG. 12A is a cross-sectional view showing the conventional method of manufacturing a circuit device and FIG. 12B is an SEM image.

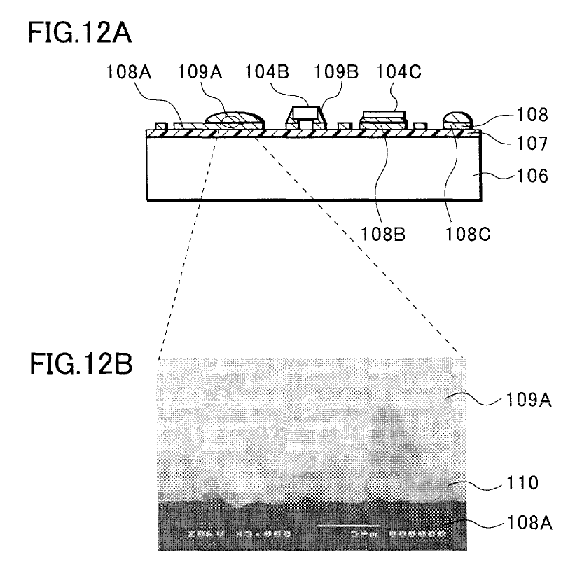

### DESCRIPTION OF THE PREFERRED EMBODIMENT

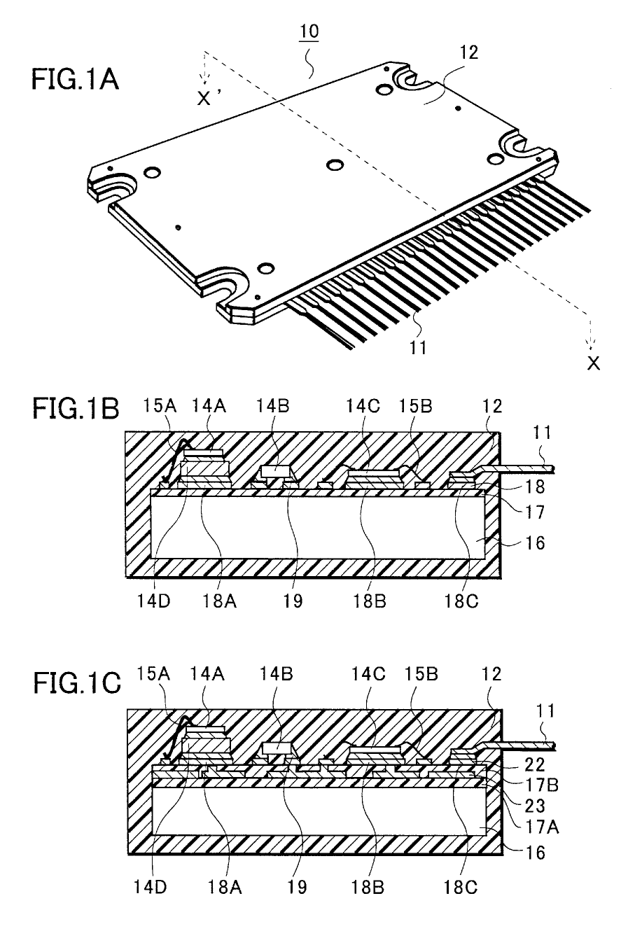

In this embodiment, a configuration of a hybrid integrated circuit device 10 that is a circuit device of the present invention will be described with reference to FIGS. 1A to 1C. FIG. 1A is a perspective view showing a hybrid integrated circuit device. FIG. 1B is a cross-sectional view thereof. FIG. 1C is a cross-sectional view showing the hybrid integrated circuit device 10 in which a multi-layered conductive pattern is formed.

As shown in FIGS. 1A and 1B, in the hybrid integrated circuit device 10, a conductive pattern 18 is formed on the surface of a substrate 16, and circuit elements including transistors and the like are fixed to the conductive pattern 18 with a solder 19. Subsequently, at least the surface of the substrate 16 is covered with a sealing resin 12.

As a substrate 16A, a metal substrate made of a metal such as aluminium or copper, or chiefly made of copper or the like is used. Besides the metal substrate, as the substrate 16A, a substrate made of a resin material such as an epoxy resin, which substrate is formed, for example, of a flexible sheet or a print circuit board is used. Alternatively, it is also possible to adopt a ceramic substrate made of alumina or the like, a glass substrate, or the like as the substrate 16. When the substrate made of aluminium is for example adopted as the substrate 16 the surface of the substrate 16 undergoes anodization treatment. A specific size of the substrate 16 has a length, breadth and thickness respectively approximately equal to, for example, 60, 40 and 1.5 mm.

An insulating layer 17 is formed so as to cover the entire surface of the substrate 16. The insulating layer 17 is made of an epoxy resin or the like, which is filled with a large amount of fillers such as Al₂O₃. Thus, heat generated from the circuit element included in the device can be actively discharged to the outside through the substrate 16. A specific thickness of the insulating layer 17 is, for example, about 50 μm.

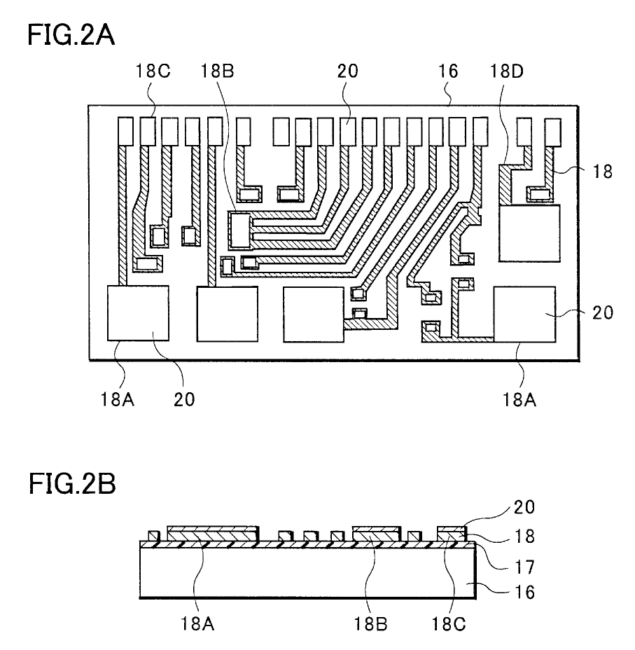

The conductive pattern 18 is formed of a material mainly made of copper and is formed on the insulating layer 17 in order that a specific electric circuit is realized. Furthermore, a pad 18A (a first pad), a pad 18B (a second pad), and a pad 18C are formed by the conductive pattern 18. Detailed descriptions of each type of the pads will be given later with reference to FIGS. 2A and 2B.

Circuit elements such as a power transistor 14A, a chip component 14B and a small signal transistor 14C are fixed to the predetermined conductive patterns 18 with the solder 19 interposed therebetween. The power transistor 14A is fixed to the pad 18A with the heat sink 14D interposed therebetween. Thus, heat release properties are improved. The chip component 14B has electrodes on its both ends, which are fixed to the conductive pattern 18 by use of the solder 19. The small signal transistor 14C is fixed to the pads 18B with the solder 19 interposed therebetween. Here, the power transistor 14A is, for example, a transistor through which a current of 1A or more flows. The small signal transistor 14C is a transistor through which a current of less than 1A flows. Furthermore, an electrode on a surface of the power transistor 14A is connected to the conductive pattern 18 through a thick wire 15A that is a thin metal wire having a thickness of 100 μm or more. Moreover, an electrode formed on a surface of the small signal transistor 14C is connected to the conductive pattern 18 through a thin wire 15B having a thickness of about 80 μm or less.

As circuit elements mounted on the substrate 16, semiconductor elements such as a transistor, an LSI chip and a diode can be adopted. Moreover, chip components such as a chip resistor, a chip condenser, an inductance, a thermistor, an antenna and an oscillator can also be adopted as the circuit elements. Furthermore, a circuit device of a plastic molding type can also be included in the hybrid integrated circuit device 10.

A lead 11 is fixed to the pad 18C provided in a peripheral part of the substrate 16 and has a function of performing input and output from and to the outside. Here, a number of leads 11 are fixed to one side of the substrate 16. Note that the leads 11 can also be derived from four sides of the substrate 16 or can also be derived from two opposite sides thereof.

The sealing resin 12 is formed by transfer molding using a thermosetting resin. As shown in FIG. 1B, the conductive pattern 18 and the circuit elements, which are formed on the surface of the substrate 16, are covered with the sealing resin 12. Here, sides and a rear surface of the substrate 16 are also covered with the sealing resin 12. By covering the entire substrate 16 with the sealing resin 12 as described above, moisture resistance of the entire device can be improved. Moreover, in order to improve heat release properties of the substrate 16, the rear surface of the substrate 16 may be exposed from the sealing resin 12. Furthermore, instead of covering with the sealing resin 12, sealing by use of a case material can also be performed.

As shown the cross-sectional view in FIG. 1C, herein, a two-layered conductive pattern formed of a first wiring layer 22 and a second wiring layer 23 is formed on the surface of the substrate 16. The surface of the substrate 16 is covered with a lower insulating layer 17A, and the second wiring layer 23 is formed on the surface of the insulating layer 17A. Furthermore, the second wiring layer 23 is covered with an upper insulating layer 17B, and the first wiring layer 22 is formed on the surface of the insulating layer 17B. The first wiring layer 22 and the second wiring layer 23 penetrate the insulating layer 17B to be connected each other at a predetermined point. Herein, the first wiring layer 22 includes the pad 18A and the like.

### Second Embodiment

In a second embodiment, a method of manufacturing the above-described hybrid integrated circuit will be described with reference to FIGS. 2A to 7B.

First Step: see FIGS. 2A and 2B

In this step, a conductive pattern 18 is formed on the surface of a substrate 16. FIG. 2A is a plan view showing the substrate 16 in this step, and FIG. 2B is a cross-sectional view thereof.

As shown in FIGS. 2A and 2B, the conductive pattern 18 having a pre-determined patterned shape is formed by patterning a conductive foil sticked to the surface of the substrate 16. Here, pads 18A to 18C are formed by the conductive pattern 18. The pad 18A (a first pad) is a pad to which a heat sink is fixed in a subsequent step, and is formed relatively large. The pad 18A is formed to be shaped like a rectangle having a size, for example, of 9 mm×9 mm or larger. The pad 18B (a second pad) is a pad to which a small signal transistor or a chip component is fixed, and is formed to be smaller than the pad 18A. The pad 18B assumes a rectangle having a size, for example, of about 2 mm×2 mm. A plurality of the pads 18C are formed at specified intervals along the upper side of the substrate 16 in FIG. 2A. A lead 11 is fixed to the pad 18C in a subsequent step. In addition, a wiring pattern 18D extended so as to connect the pads thereto is also formed.

Surfaces respectively of the pads 18A, 18B, and 18C are covered with a plated film 20 made of nickel. Formation of the plated film 20 suppresses the sink of solder formed on the pads. Detailed descriptions thereof will be given below. Additionally, the plated film 20 made of nickel is also formed in each of areas where thin metallic wires are bonded to improve bonding performances thereof.

This plated film 20 may be formed only on the pads 18A on which sink of solder would otherwise occur or on all pads. In addition, the plated film 20 is also formed on the upper surfaces of bonding pads to facilitate formation of metallic wires.

In this embodiment, the plated film 20 is preferably formed by use of an electrolytic plating method. Methods of forming a plated film include the electrolytic plating method and a non-electrolytic plating method, and it is possible to form the plated film 20 by use of either methods. However, if the plated film 20 is formed by use of the non-electrolytic plating method, phosphorus (P) used as a catalyst is contained in the plated film 20. Accordingly, phosphorus is also contained in an alloy layer formed at the interface between the plated film 20 and a solder 19. Mechanical strength of the alloy layer containing phosphorus is lowered. Accordingly, there arises a problem that the alloy layer is easily peeled off from the plated film 20 when stress is applied to the alloy layer while being used. On the other hand, in a case of using the electrolytic plating method, no phosphorus is used and accordingly is contained in the plated film 20 to be formed. Therefore, it is made possible to form the plated film 20 and the alloy layer excellent in mechanical strength.

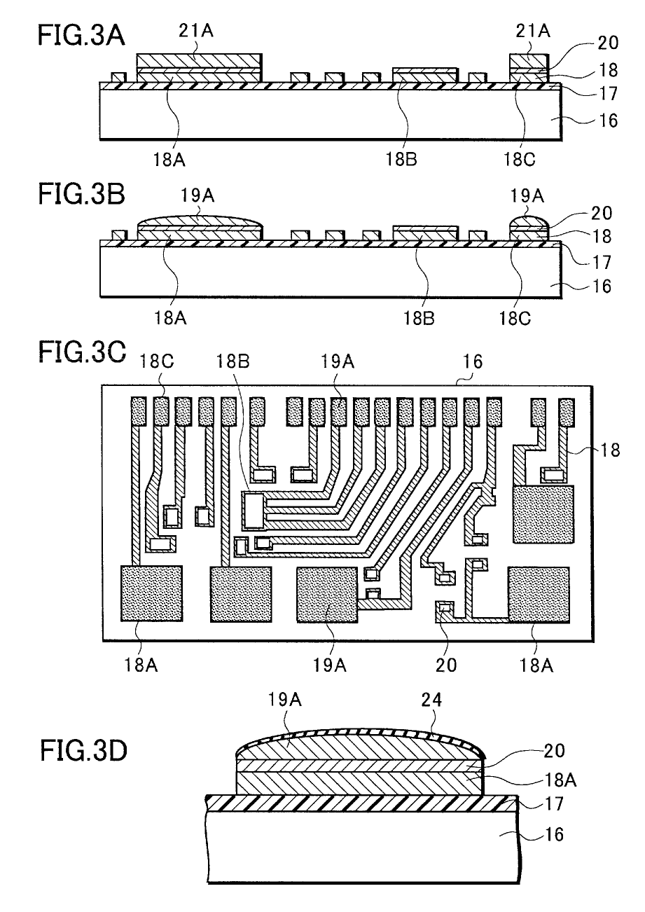

Second Step: see FIGS. 3A to 3D

In this step, solder 19A is formed on the pads 18A and 18C.

First, as shown in FIG. 3A, screen printing is performed to apply solder paste 21A to the upper surfaces of the pads 18A and 18C. In this step, the solder paste 21A is applied to a relatively large pad or a pad using more solder. Since the heat sink is fixed to the pad 18A in the subsequent step, the pad 18A is formed to have a rectangular shape with a length of 9 mm or more on a side as described above. Moreover, since a lead frame is fixed to the pad 18C in the subsequent step, a large amount of the solder paste 21A is applied thereto.

It is preferable that the solder paste 21A used in this step be a mixture of flux containing sulfur and solder powder. Sulfur is mixed in a proportion of 20 to 80 PPM into the flux. By mixing sulfur into the flux within such a concentration range, surface tension of the flux is reduced. Thus, wettability of the solder paste 21A can be improved. If the amount of sulfur is 20 PPM or less, the effect of improving the wettability is not sufficient. Consequently, there is a risk of occurrence of sink. Furthermore, if the amount of sulfur is 80 PPM or more, a nucleus of mixed sulfur remains in the solder. Thus, there is a risk that a local depression might be formed in the surface of the solder.

As a method of manufacturing the solder paste 21A, first, granular sulfur (S) is dissolved in a solvent. Next, after the solvent containing sulfur and flux are mixed, the flux and solder powder are mixed. A proportion of the flux contained in the solder paste 21A is, for example, about 5 to 15 wt %.

As the solder powder mixed in the solder paste 21A, both of solder containing lead and lead-free solder can be adopted. As a specific composition of the solder powder, for example, Sn63/Pb37, Sn/Ag3.5, Sn/Ag3.5/Cu0.5, Sn/Ag2.9/Cu0.5, Sn/Ag3.0/Cu0.5, Sn/Bi58, Sn/Cu0.7, Sn/Zn9, Sn/Zn8/Bi3 and the like are conceivable. The numbers described above indicate wt % relative to the entire solder. Considering that lead has a load significantly affecting on the environment, it is preferable to use the lead-free solder. The solder paste 21A containing the lead-free solder tends to have poor solder wettability. However, the surface tension of the flux is reduced by action of the added sulfur. Thus, occurrence of sink is suppressed.

As the flux, rosin-based flux and water-soluble flux are both applicable. However, the water-soluble flux is preferable. This is because the water-soluble flux has strong soldering properties and is suitable for attaching the solder 19A to the entire surface of the pad 18A. When the water-soluble flux is used, by melting of the solder paste 21A, a highly corrosive flux residue is generated. Therefore, in this embodiment, after a reflow step is finished, the residue is cleaned and removed.

The flux used in this embodiment is a RA type having a very strong active force. By using the flux of the RA type, even if an oxide film is formed on the surface of the plated film 20, the oxide film can be removed by the flux. Therefore, in this embodiment, it is not required to cover the surface of the plated film 20 with gold plating or the like in order to prevent formation of the oxide film. Generally, the flux is classified broadly into a R type (Rosin base), a RMA type (Mildly Activated Rosin base) and a RA type (Activated Rosin base) in the order from a weaker active force. In this embodiment, the flux of the RA type having the strongest active force is used.

In this embodiment, before the circuit elements are mounted, the melted solder 19A is previously formed on the large pad 18A. This is because, in this embodiment, mounting of the circuit elements is sequentially performed from a relatively small circuit element such as a small signal transistor. After the circuit element such as the small signal transistor is fixed, it is difficult to print the solder paste on the upper surface of the large pad 18A. Thus, by preparing the solder 19A melted on the pad 18A, the problem described above can be avoided.

As shown in FIGS. 3B and 3C, next, the solder paste 21A is melted by the reflow step of performing heating and melting, and the solder 19A is formed on the upper surfaces of the pads 18A and 18C. FIG. 3B is a cross-sectional view of the substrate 16 after the solder 19A is formed, and FIG. 3C is a plan view thereof.

The heating and melting of the solder paste 21A is performed by heating a rear surface of the substrate 16 by use of a heater block and performing infrared irradiation from above. If the solder paste 21A contains tin-lead eutectic solder, a reflow temperature is about 220° C. Moreover, if the solder paste 21A is the lead-free solder (for example, Sn/Ag3.5/Cu0.5), the reflow temperature is about 250° C.

In this embodiment, by allowing the solder paste 21A to contain sulfur in a predetermined proportion, the solder 19A can be formed by heating and melting the solder paste 21A while suppressing sink of the solder. Therefore, as shown in FIG. 3C, the surfaces of the pads 18A and 18C are entirely covered with the solder 19A. Particularly, in the large pad 18A to which the heat sink is fixed, the sink tends to occur. However, the use of the solder paste 21A of this embodiment, which contains sulfur, can eliminate the risk described above.

FIG. 3D is an enlarged cross-sectional view of the pad 18A on which the solder 19A is formed. As shown in FIG. 3D, by melting the solder paste 21A containing sulfur, the solder 19A is formed on the entire upper surface of the pad 18A. Therefore, the upper surface of the solder 19A is set to be a smoothly curved surface similar to a flat surface. A flux 24 is generated when the solder paste 21A is melted. Then, the flux 24 is attached to the upper surface of the solder 19A. Accordingly, the amount of the flux flowing out to the surrounding is limited. Thus, it is possible to prevent the surrounding pattern from being corroded by the highly corrosive flux. As described above, the flux used in this embodiment is the RA type having the strongest active force. The flux of the RA type having the strong active force also has a strong oxidizing power. Thus, if the flux leaks out on the surface of the substrate 16, the conductive pattern 18 may be corroded. Therefore, in this embodiment, the upper surface of the solder 19A is set to be a smoothly curved surface, and the flux 24 is attached to the upper surface of the solder 19A. Thus, the flux is prevented from leaking out to the surrounding.

Furthermore, in this embodiment, the plated film 20 is formed on the surface of the pad 18A. This also contributes to prevention of sink. Specifically, it is possible to prevent the solder 19A and the pad 18A from directly contacting each other, by forming the plated film 20 made of copper on the surface of the pad 18A and by forming the solder 19A on the surface of the plated film 20. Accordingly, an intermetallic compound made of tin, which is a main component of solder, as well as copper, which is a material of the pad, is not generated. With method of this embodiment, an intermetallic compound made of tin, which is a main component of the solder, and nickel, which is a material of the plated film 20, is generated. In addition, the intermetallic compound made of tin and nickel is more excellent in solder wettability than the intermetallic compound made of tin and copper. Accordingly, in this embodiment, occurrence of sink due to low solder wettability of the intermetallic compound is suppressed.

It is considered that by heating and melting the solder paste 21A, most of sulfur flows out to the outside of the solder 19A together with the flux component. However, there is also a possibility that a very small amount of sulfur remains in the solder 19A and reduces the surface tension of the melted solder 19A in a subsequent step of remelting the solder 19A.

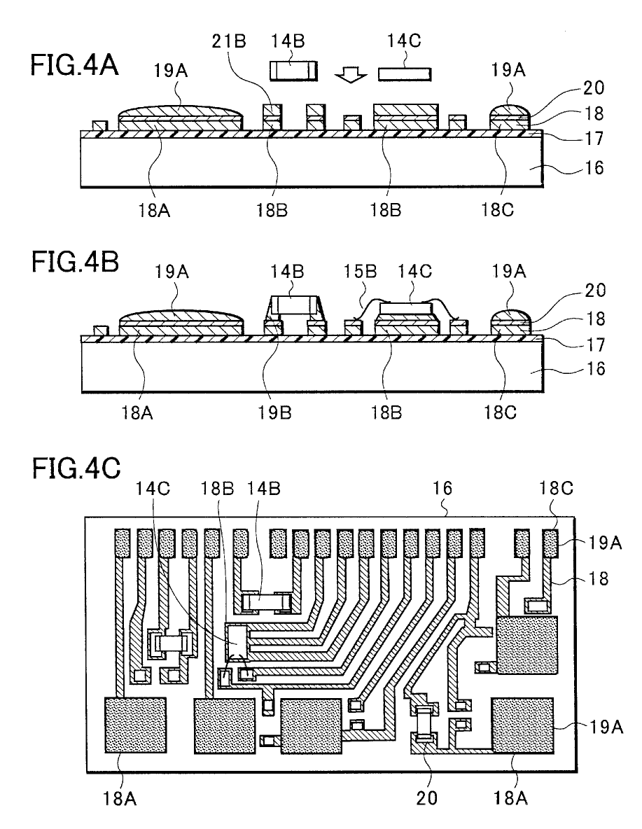

Third Step: see FIGS. 4A to 4C

In this step, a small signal transistor and the like are fixed to the substrate 16.

As shown in FIG. 4A, first, solder paste 21B is applied to the upper surface of the pad 18B by screen printing. Thereafter, a chip component 14B and a transistor 14C are temporarily mounted on the solder paste 21B. The solder paste 21B used in this step is preferably one containing rosin-based flux. By using the rosin-based flux which is less corrosive than water-soluble flux, it is possible to prevent corrosion of the conductive pattern 18 positioned around the pad 18B. Moreover, as the solder paste 21B, the solder paste containing sulfur, which is used in the preceding step, may be used or solder paste containing no sulfur may be used. The pad 18B is a small pad to which the small signal transistor 14C, the chip component 14B or the like is fixed. Therefore, compared with the large pad 18A, there is less risk that sink of the solder occurs.

As shown in FIG. 4B, next, by heating and melting the solder paste 21B on which the chip component 14B and the like are mounted, the circuit elements described above are fixed. A reflow temperature in this step is the same as that in the preceding step where the solder 19A is melted. Therefore, by melting the solder paste 21B to form solder 19B, the solder 19A formed on the pad 18A is also remelted.

However, in this embodiment, since the upper surface of the pad 18A is covered with the plated film 20, no intermetallic compound made of copper, which is a material of the pad 18A, as well as the solder 19A is formed. Accordingly, the occurrence of sink due to remelting of the solder 19A is suppressed. Furthermore, the small signal transistor 14C is electrically connected to the conductive pattern 18 through a thin wire 15B.

In this embodiment, it is also possible to omit the plated film 20 formed on the surface of the pad 18A. If no plated film 20 is formed thereon, the solder 19A directly contacts with the pad 18A, and an alloy layer made of copper and tin, which has poor soldering properties, is formed. In this embodiment, even in a case where the alloy layer is formed, since a solder paste into which sulfur is mixed is used. As a result, the occurrence of sink is suppressed.

In this case, the small signal transistor 14C may be fixed with a conductive paste such as an Ag paste.

FIG. 4C shows a plan view of the substrate 16 after this step is finished. In the solder 19A formed on the surface of the pad 18A, no sink occurs. Specifically, the entire surface of the pad 18A is covered with the solder 19A.

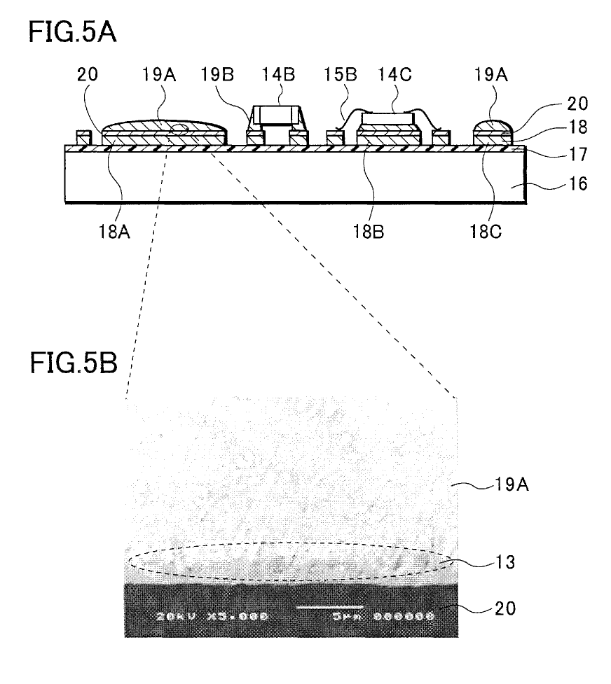

With reference to FIGS. 5A and 5B, detailed description will be given of the boundary between the solder 19A and the plated film 20 after the step described above is finished. FIG. 5A is a cross-sectional view of the substrate 16 after the step described above is finished, and FIG. 5B shows a SEM image of the boundary between the solder 19A and the plated film 20.

As shown in FIG. 5B, an alloy layer 13 having a thickness of about 2 μm is generated on the boundary between the solder 19A and the plated film 20. As described above, the alloy layer 13 is made of tin contained in the solder 19A and nickel that is the material of the plated film 20. A rate at which the alloy layer 13 of this embodiment is generated is much slower than that of the alloy layer containing copper, which has been described in the background.

Moreover, nickel becomes a barrier film of Cu formed therebelow and can suppress deposition of Cu on a surface of Ni. Thus, a reaction of Cu and Sn is suppressed as much as possible, and occurrence of sink is suppressed. Furthermore, a surface of the alloy layer 13 is set to be a rough surface compared with that described in the background. Thus, the surface of the alloy layer 13 is an environment where it is difficult for the liquefied solder 19A to move. This also contributes to prevention of the sink.

Furthermore, in this embodiment, by covering the surfaces of the pads 18A and the like with the plated film 20, it is possible to prevent destruction of a connection part at which a connection is made with the solder 19A. Specifically, since the surface of the pad 18A and the like are covered with the plated film 20 made of nickel, no pad 18A made of copper directly contacts with the solder 19A. Accordingly, no fragile metallic compound made of tin, which is contained in the solder 19A, as well as copper, which is a material of the pads 18A, is generated. Additionally, it is less problematic that the metallic compound further grows, even when the pads 18A and the solder 19A are heated because circuit elements such as transistors and the like generate heat. The alloy layer 13 made of nickel and tin is formed in the interface between the plated film 20 and the solder 19A because the surface of the pads 18A is covered with the plated film 20A. The alloy layer 13 is more excellent in mechanical strength than the alloy layer made of copper and tin. Accordingly, under use, transistors and the like operate, whereby the alloy layer 13 grown due to heating of the solder 19A. Even in such a case, the solder 19A and the plated film 20 would be hardly destroyed.

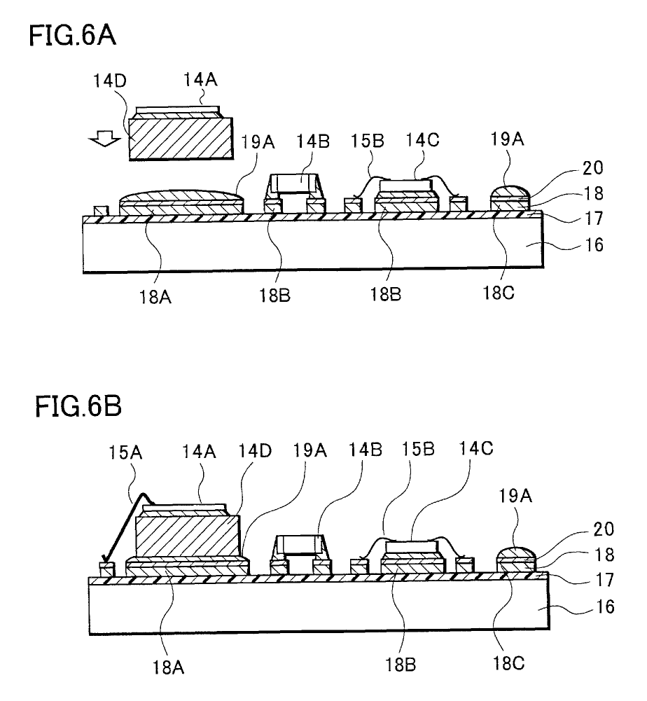

Fourth Step: see FIGS. 6A and 6B

In this step, a heat sink 14D is mounted on the pad 18A.

As shown in FIG. 6A, first, the heat sink 14D having a power transistor 14A fixed thereon is mounted on the solder 19A formed on the pad 18A. Thereafter, by using a hot plate to heat the substrate 16, the solder 19A formed on the pad 18A is remelted. Thus, the heat sink 14D is fixed to the pad 18A. Here, a specific size of the heat sink 14D is about length×breadth×thickness=8 mm×8 mm×2 mm. In this embodiment, instead of the method using the hot plate, the solder may be melted in a reflow step using a reflow furnace.

As shown in FIG. 6B, next, an emitter electrode and a base electrode of the power transistor 14A are connected to the predetermined conductive pattern 18 by use of a thick wire 15A having a diameter of about 300 μm.

In this embodiment, after the small signal transistor 14C is fixed and the thin wire 15B is formed, the heat sink 14D is fixed. This is because it is difficult to dispose the transistor 14C and form the thin wire 15B in the vicinity of the heat sink 14D after the heat sink 14D is fixed. By disposing the heat sink 14D that is a large circuit element after a small circuit element is fixed, the small circuit element can be disposed near the heat sink 14D.

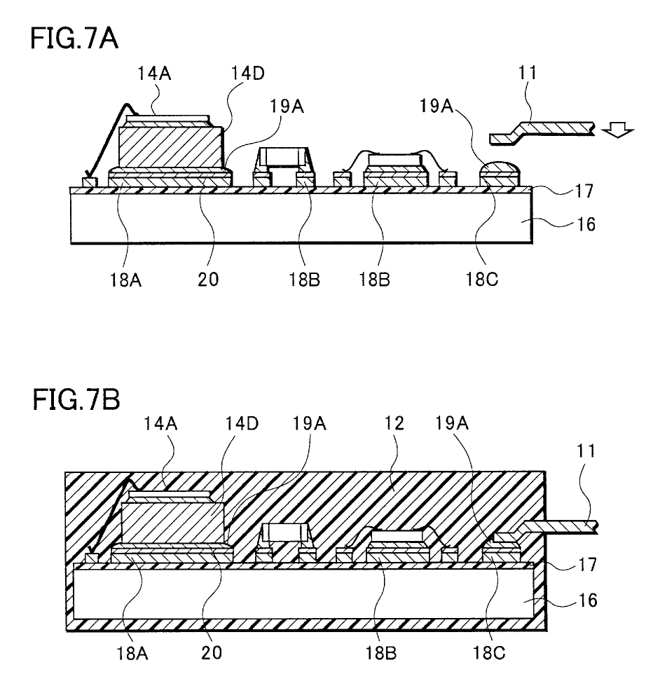

Fifth Step: see FIGS. 7A and 7B

In this step, the lead 11 is fixed and a sealing resin 12 is formed.

As shown in FIG. 7A, first, the lead 11 is mounted on the pad 18C. Thereafter, the solder 19A is melted to fix the lead. To be more specific, the solder 19A is melted by irradiation of a light beam while heating the substrate 16 by use of a hot plate. Thus, the lead 11 is fixed.

As shown in FIG. 7B, the sealing resin 12 is formed so as to cover the circuit elements fixed to the surface of the substrate 16. Specifically, the sealing resin 12 is formed so as to cover the side surfaces of the substrate 16 as well as the back surface thereof. Herein, the sealing resin 12 may also be formed with the lower surface of the pad being exposed outside. In addition, it is also possible to seal the surface of the substrate 16 by use of a case member. The hybrid integrated circuit device 10 as shown in FIGS. 1A to 1C is formed by use of the above-described steps.

In this embodiment, to mix sulfur in the solder paste prevents the occurrence of sink at the time of a primary solder melting. Furthermore, the occurrence of sink at the time of secondary and subsequent solder melting is prevented by provision of the plated film 20 made of nickel to the surface of the pad on which solder is formed.

At the time of the primary melting, as shown in FIG. 3A, a solder paste 21A is applied to the surface of the large pad 18A having a length and breadth respectively of 1 cm, and the solder paste 21A is melted thereon. In a case where the paste 21A is applied to and melted on the aforementioned large pad 18A, surface tension which acts on the melted solder is high. As a result, a risk that the sink occurs becomes more significant. In this embodiment, sulfur is mixed into the solder paste 21A to reduce the surface tension on the melted solder. Accordingly, the occurrence of sink is prevented.

At the time of the secondary and subsequent melting, as shown in FIGS. 5A and 5B, for example, the plated film 20 which is made of nickel and formed on the surface of the pad 18A prevents the sink from occurring in the melted solder 19A. A flux contained in the solder paste leaks outside at the time of the aforementioned primary melting. Accordingly, it is impossible to expect an effect of preventing the occurrence of the flux, which may occur at the time of the secondary and subsequent melting.

In this embodiment, the surface of the pad 18A is covered with the plated film 20 made of nickel to prevent formation of a Cu/Sn alloy layer with poor solder wettability, which layer is described in the background art. Specifically, no solder 19A directly contacts with the surface of the pad 18A made of copper as the pad 18A made of copper is covered with the plated film 20 made of nickel. Accordingly, no Cu/Sn alloy layer made of copper, which is a material of the pads 18A, as well as tin, which is a material of the solder 19A, is formed. In this embodiment, as shown in FIG. 5B, the alloy layer 13 made of nickel and tin is formed on the surface of the plated film 20. In addition, since this alloy layer 13 is more excellent in solder wettability than (in comparison with) the Cu/Sn alloy layer, the occurrence of sink is suppressed at the time of the secondary and subsequent melting of the solder 19A.

### Third Embodiment

In this embodiment, description will be given of another method of manufacturing a hybrid integrated circuit device. Here, solder paste is collectively melted to fix circuit elements.

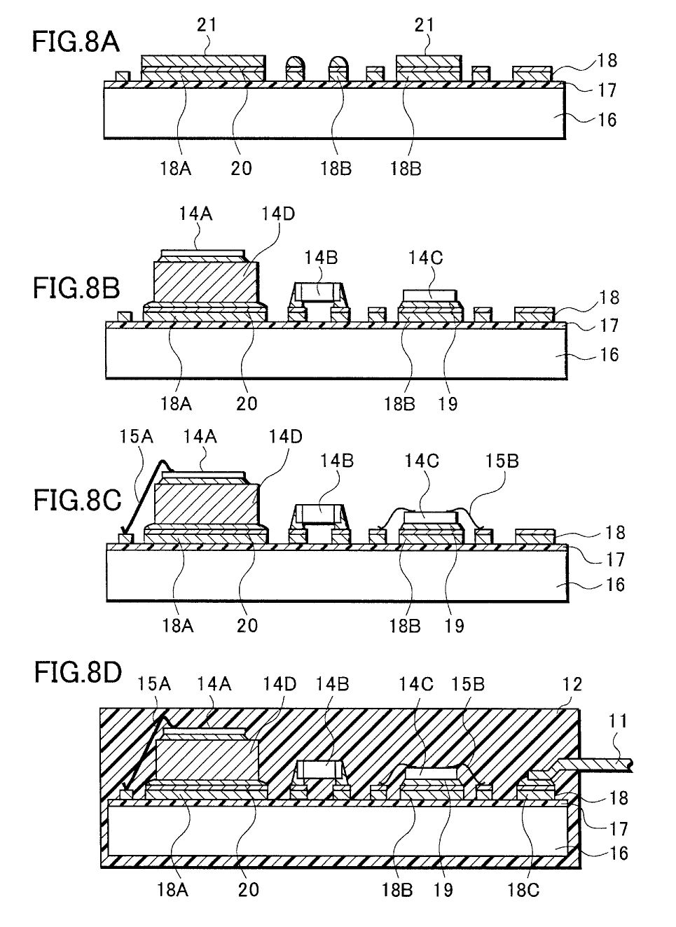

As shown in FIG. 8A, first, a substrate 16 on which a conductive pattern 18 is formed is prepared, and solder paste 21 is applied to desired pads. In this embodiment, the conductive pattern 18 forms pads 18A and 18B. The pad 18A is a pad to which a heat sink is fixed, and is formed to be as large as about 9 mm×9 mm or more, for example. The pad 18B is a pad to which a chip component such as a chip resistor or a small signal transistor is fixed, and is formed to be smaller than the pad 18A.

The solder paste 21 used in this step is the one into which sulfur is mixed similarly in the second embodiment. Sulfur is mixed in a proportion of 20 to 80 PPM into the flux. The addition of sulfur therein lowers the surface tension on the melted solder paste 21.

As shown in FIG. 8B, next, after a circuit element such as a heat sink 14D is temporarily attached to the solder paste 21, reflow is performed to fix the circuit element. To be more specific, the heat sink 14D having a power transistor 14A mounted thereon is temporarily attached to the pad 18A by use of a chip mounter. Thereafter, a chip component 14B and a small signal transistor 14C are temporarily attached to the small pad 18B. Furthermore, after temporary attachment of the circuit elements described above is all finished, heating and melting are performed to melt the solder paste. Thus, the circuit elements are fixed by use of a solder 19. In this step, by using the solder paste containing sulfur, sink of the solder is suppressed. Furthermore, in this step, the elements fixed by use of the solder are collectively reflowed. Thus, there is an advantage that the manufacturing steps can be shortened. Moreover, after the reflow of the solder is finished, a small signal transistor may be fixed by use of conductive paste such as Ag paste.

As shown in FIG. 8C, next, the desired conductive pattern 18 and the circuit elements are connected to each other through thin metal wires. To be more specific, electrodes of the small signal transistor 14C are connected to the desired conductive pattern 18 by use of thin wires 15B made of aluminum wires having a diameter of about 80 μm. Moreover, an electrode of the power transistor 14A is connected to the desired conductive pattern 18 by use of a thick wire 15A made of an aluminum wire having a diameter of about 300 μm.

As shown in FIG. 8D, next, a lead 11 is fixed to a pad 18C provided in a peripheral part of the substrate 16. Thereafter, a sealing resin 12 is formed so as to cover at least the surface of the substrate 16. By the steps described above, a hybrid integrated circuit device is manufactured.

In this embodiment, the circuit elements fixed by use of the solder paste are collectively reflowed. Thus, it is possible to provide a manufacturing method including reduced steps.

According to the manufacturing method of a circuit device of the present invention, since a solder paste into which sulfur is mixed is used, the occurrence of sink in solder is suppressed even in a case where the solder paste is melted after having been applied to a relatively large pad. Especially, even in a case where the solder paste is applied to a pad to which a large circuit element such as a heat sink is fixed and then the paste is melted thereon, it is possible to suppress the occurrence of sink in the melted solder Moreover, even in a case where a solder paste into which lead-free solder with low wettability is mixed is used, occurrence of sink is suppressed because surface tension can be lowered due to sulfur mixed into a flux.

What is claimed is:

1. A method of manufacturing a circuit device, comprising:
forming a conductive pattern including a pad on a surface of a substrate;
applying a solder paste to a surface of the pad; and
placing a circuit element on the solder paste and then thermally melting the solder paste, thus fixing the circuit element to the pad,
wherein the solder paste contains sulfur.

2. A method of manufacturing a circuit device, comprising:
forming a conductive pattern including a first pad and a second pad smaller than the first pad on a surface of a substrate;
applying a solder paste to a surface of the first pad and then thermally melting the solder paste, thus forming solder on the surface of the first pad;
fixing a circuit element to the second pad; and
fixing a circuit element to the first pad while interposing the solder therebetween;
wherein the solder paste applied to the first pad contains sulfur.

3. The method according to claim 1, wherein the sulfur is mixed in a proportion of 20 to 80 PPM into the flux composing the solder.

4. The method according to claim 2, wherein the sulfur is mixed in a proportion of 20 to 80 PPM into the flux composing the solder.

5. The method according to claim 2, further comprising the step of: removing a residual flux by cleansing the surface of the substrate, after the solder is formed.

6. The method according to claim 2, wherein any one of a heat sink and a lead is fixed to the first pad.

7. The method according to claim 1, wherein the solder paste is a lead-free solder paste.

8. The method according to claim 2, wherein the solder paste is a lead-free solder paste.

9. The method according to claim 1, wherein the solder paste contains a water-soluble flux.

10. The method according to claim 2, wherein the solder paste contains a water-soluble flux.

11. The method according to claim 1, wherein the surface of the pad is covered with a plated film made of nickel.

12. The method according to claim 11, wherein an intermetallic compound made of the solder and nickel is formed between the solder and the plating layer covering the pad, and
wherein the intermetallic compound is more excellent in wettability than a metallic compound made of solder and copper which is a material of the pad.

13. The method according to claim 2, wherein the surface of the first pad is covered with a plated film made of nickel.

14. The method according to claim 13, wherein an intermetallic compound made of the solder and nickel is formed between the solder and the plated film covering the first pad, and
wherein the intermetallic compound is more excellent in wettability than a metallic compound made of solder and copper which is a material of the first pad.
